(19) United States
(12) Patent Application Publication
(10) Pub. No.: US 2025/0252972 A1
(43) Pub. Date: Aug. 7, 2025

(54) DISK DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hayato YAMAGUCHI, Sagamihara Kanagawa (JP); Nobuhiro YAMAMOTO, Yokohama Kanagawa (JP); Taichi OKANO, Yokohama Kanagawa (JP); Yoshiko TAKAHASHI, Yokohama Kanagawa (JP); Yoshihiro AMEMIYA, Chigasaki Kanagawa (JP); Shinra YAMANAKA, Yokohama Kanagawa (JP)

(21) Appl. No.: 18/829,113

(22) Filed: Sep. 9, 2024

(30) Foreign Application Priority Data
Feb. 2, 2024 (JP) 2024-014556

(51) Int. Cl. G11B 5/48; H05K 1/11; H05K 1/18

(52) U.S. Cl. CPC G11B 5/4853; H05K 1/118; H05K 1/189; H05K 2201/10159

(57) ABSTRACT

A disk device according to an embodiment includes an electronic component, a first adhesive, a plate, and a first bonding layer. The flexible printed circuit board has a first surface facing the electronic component, a second surface located opposite to the first surface, and a pad provided on the first surface and connected to the electronic component by a conductive adhesive. The first adhesive is provided on the second surface. The plate has a third surface facing the second surface. The first bonding layer is provided on the third surface, enters a recess of the third surface, and is fixed to the second surface by the first adhesive.

### CROSS-REFERENCE TO RELATED APPLICATIONS

This application is based upon and claims the benefit of priority from Japanese Patent Application No. 2024-014556, filed on Feb. 2, 2024; the entire contents of which are incorporated herein by reference.

### FIELD

Embodiments described herein relate generally to a disk device.

### BACKGROUND

A disk device such as a hard disk drive (HDD) includes a flexible printed circuit board (FPC), an electronic component connected to the FPC by a conductive adhesive, and a plate bonded to the FPC. For example, a flexure is connected to the FPC by soldering, and a metal reinforcing plate is bonded to the FPC.

For example, at the time of heating the joint body, the plate might be peeled off from an adhesive that bonds the plate to the FPC.

### BRIEF DESCRIPTION OF THE DRAWINGS

FIG. 1 is an exemplary perspective view illustrating an HDD according to a first embodiment in an exploded manner;

FIG. 2 is an exemplary view schematically illustrating an FPC and a flexure according to the first embodiment in an exploded manner;

FIG. 3 is an exemplary plan view schematically illustrating a carriage, the FPC, and a part of the flexure according to the first embodiment;

FIG. 4 is an exemplary cross-sectional view schematically illustrating a part of the carriage and the FPC according to the first embodiment taken along line F4-F4 of FIG. 3;

FIG. 5 is an exemplary cross-sectional view schematically illustrating a part of a carriage and an FPC according to a second embodiment;

FIG. 6 is an exemplary cross-sectional view schematically illustrating a part of a carriage and an FPC according to a third embodiment;

FIG. 7 is an exemplary plan view schematically illustrating a carriage, an FPC, and a part of a flexure according to a fourth embodiment;

FIG. 8 is an exemplary cross-sectional view schematically illustrating a part of the carriage and the FPC according to the fourth embodiment taken along line F8-F8 of FIG. 7;

FIG. 9 is an exemplary cross-sectional view schematically illustrating a carriage and an FPC according to a fifth embodiment;

FIG. 10 is an exemplary plan view schematically illustrating a carriage, an FPC, and a part of a flexure according to a sixth embodiment; and

FIG. 11 is an exemplary plan view schematically illustrating a carriage, an FPC, and a part of a flexure according to a seventh embodiment.

### DETAILED DESCRIPTION

In general, according to an embodiment, a disk device includes an electronic component, a first adhesive, a plate, and a first bonding layer. The flexible printed circuit board has a first surface facing the electronic component, a second surface located opposite to the first surface, and a pad provided on the first surface and connected to the electronic component by a conductive adhesive. The first adhesive is provided on the second surface. The plate has a third surface facing the second surface. The first bonding layer is provided on the third surface, enters a recess of the third surface, and is fixed to the second surface by the first adhesive.

### First Embodiment

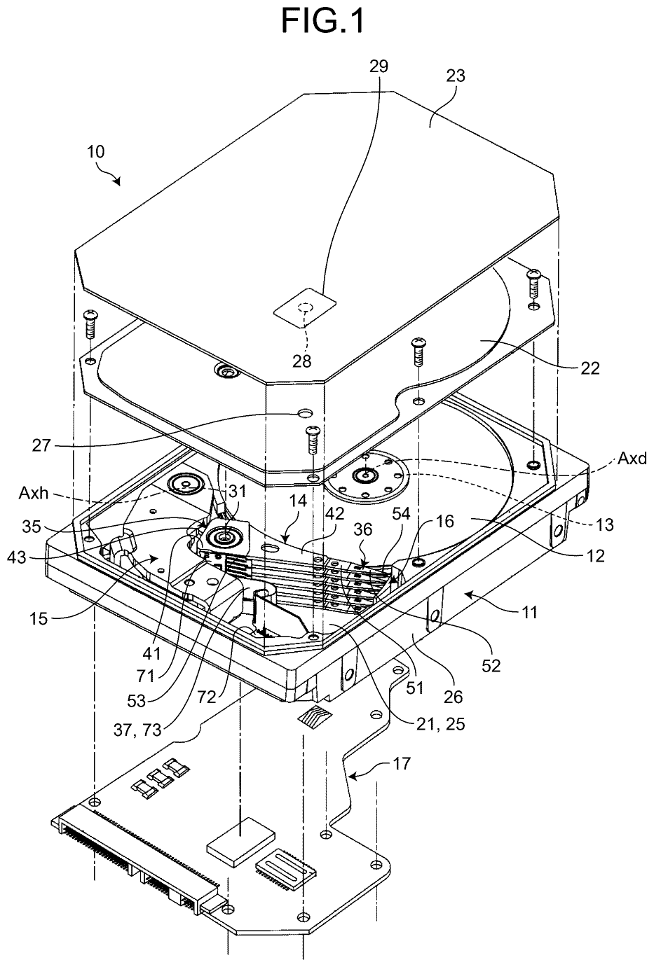

In the following, a first embodiment will be described with reference to FIGS. 1 to 4. Note that in the present specification, components according to embodiments and descriptions of the components may be recited in a plurality of expressions. The components and the description thereof are examples, and are not limited by the expressions of the present specification. The components may also be identified with names different from those in the present specification. In addition, the components can be described by expressions different from the expressions in the present specification.

In the following description, “suppress” is defined as, for example, preventing occurrence of an event, an action, or an influence, or reducing a degree of the event, the action, or the influence. In addition, in the following description, “restrict” is defined as, for example, preventing movement or rotation, or allowing movement or rotation within a predetermined range and preventing movement or rotation beyond the predetermined range.

FIG. 1 is an exemplary perspective view illustrating a hard disk drive (HDD) 10 according to the first embodiment in an exploded manner. The HDD 10 is an example of a disk device, and may also be referred to as an electronic apparatus, a storage device, an external storage device, or a magnetic disk device.

As illustrated in FIG. 1, the HDD 10 has a housing 11, a plurality of magnetic disks 12, a spindle motor 13, a head stack assembly. (HSA) 14, a voice coil motor (VCM) 15, a ramp load mechanism 16, and a printed circuit board (PCB) 17. Note that the HDD 10 is not limited to this example.

The housing 11 houses the magnetic disk 12, the spindle motor 13, the HSA 14, the VCM 15, and the ramp load mechanism 16. The housing 11 has a base 21, an inner cover 22, and an outer cover 23.

The base 21 is formed in a substantially rectangular parallelepiped box shape opened in one direction. The base 21 has a bottom wall 25 and a side wall 26. The bottom wall 25 is formed in a substantially rectangular (quadrangular) plate shape. The side wall 26 protrudes from an edge of the bottom wall 25 and is formed in a substantially rectangular frame shape.

The inner cover 22 is attached to an end of the side wall 26 with a screw to close a space in the base 21. The outer cover 23 covers the inner cover 22 and is attached to the end of the side wall 26 by welding, for example. The inner cover 22 is provided with a vent 27. Furthermore, the outer cover 23 is provided with a vent 28.

After the components are attached to the inside of the base 21, and the inner cover 22 and the outer cover 23 are attached to the base 21, air inside the housing 11 is removed from the vents 27 and 28. Furthermore, the inside of the housing 11 is filled with a gas different from air.

The gas filled in the housing 11 is, for example, a low density gas having a density lower than that of air, an inert gas having low reactivity, or the like. For example, helium is filled inside the housing 11. Note that the inside of the housing 11 may be filled with other fluid.

The vent 28 of the outer cover 23 is closed by a seal 29. The seal 29 hermetically seals the vent 28 to restrict the fluid filled inside the housing 11 from leaking out from the vent 28.

The plurality of magnetic disks 12 are formed in a substantially disk shape. A magnetic recording layer is provided on at least one of an upper surface and a lower surface of the magnetic disk 12. The plurality of magnetic disks 12 are overlapped at intervals.

The spindle motor 13 supports the plurality of magnetic disks 12. The spindle motor 13 rotates the plurality of magnetic disks 12 about a central axis Axd of the spindle motor 13. The plurality of magnetic disks 12 are held at a hub of the spindle motor 13 by, for example, a clamp spring.

The HSA 14 is rotatably supported by a support shaft 31. The support shaft 31 is provided at a position separated from the magnetic disk 12 in a direction orthogonal to the central axis Axd. The support shaft 31 protrudes from the bottom wall 25 of the housing 11.

The HSA 14 can rotate about a central axis Axh. The central axis Axh is a virtual axis extending substantially parallel to the central axis Axd of the magnetic disk 12. The central axis Axh is, for example, the center of rotation of the HSA 14 and also a central axis of the support shaft 31.

The HSA 14 has a carriage 35, a plurality of head gimbal assemblies (HGA) 36, and a flexible printed circuit board (FPC) 37. The carriage 35 has an actuator block 41 and a plurality of arms 42.

The actuator block 41 is supported by the support shaft 31 so as to be rotatable via a bearing, for example. The plurality of arms 42 protrude from the actuator block 41 in a direction orthogonal to the central axis Axh. Note that the carriage 35 may be divided, and the arm 42 may protrude from each of a plurality of the actuator blocks 41.

The plurality of arms 42 extend substantially in parallel and are arranged at intervals along the central axis Axh. Each of the arms 42 is formed in a plate shape enabling entering a gap between two adjacent magnetic disks of the plurality of magnetic disks 12.

A voice coil of the VCM 15 is attached to the actuator block 41. The support shaft 31 is located between the arm 42 and the voice coil. The VCM 15 has the voice coil, a pair of yokes, and magnets provided on the yokes.

The plurality of HGA 36 are attached to corresponding one distal end of the plurality of arms 42. As a result, the plurality of HGA 36 are arranged at intervals along the central axis Axh. Each of the plurality of HGA 36 has a base plate 51, a load beam 52, a flexure 53, and a magnetic head 54. The flexure 53 is an example of an electronic component. The magnetic head 54 may also be referred to as a slider.

The base plate 51 is formed in a plate shape and is attached to the distal end of the arm 42. The load beam 52 is formed in a plate shape thinner than the base plate 51. The load beam 52 is attached to the base plate 51 so as to protrude from the base plate 51.

The flexure 53 is a kind of flexible printed wiring board formed in an elongated belt shape. The flexure 53 has a metal backing layer, an insulative base layer, a conductive layer, and a cover layer of an insulation layer.

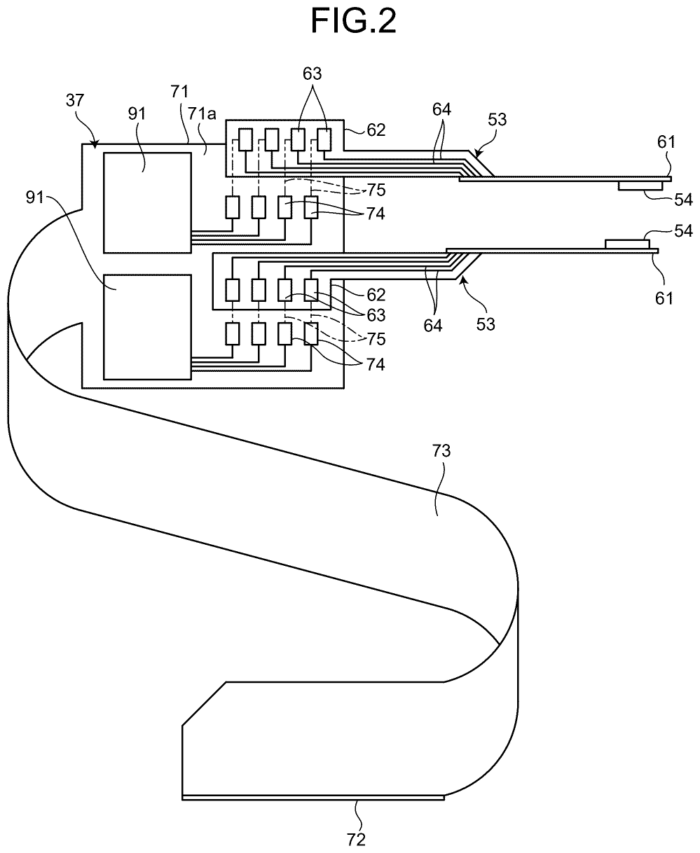

FIG. 2 is an exemplary view schematically illustrating the FPC 37 and the flexure 53 according to the first embodiment in an exploded manner. As illustrated in FIG. 2, the flexure 53 has, for example, a gimbal 61, a tail 62, a plurality of pads 63, and a plurality of wirings 64.

The gimbal 61 is provided at one end of the flexure 53. The magnetic head 54 is mounted on the gimbal 61. The gimbal 61 is attached to the load beam 52 such that a part of the gimbal 61 on which the magnetic head 54 is mounted is rotatable.

The tail 62 is provided at the other end of the flexure 53. The tail 62 extends, for example, along the arm 42. The pad 63 and the wiring 64 are provided on a conductive layer of the flexure 53.

The plurality of pads 63 are arranged on the tail 62. The plurality of pads 63 are spaced apart in a longitudinal direction of the tail 62 to form a flying lead. The plurality of wirings 64 extend between the gimbal 61 and the tail 62. Each of the plurality of wirings 64 electrically connects at least one of the plurality of pads 63 to a read element, a write element, a heater, or another component of the magnetic head 54.

The FPC 37 is formed in, for example, a belt shape. The FPC 37 has two joint portions 71 and 72, a flexible portion 73, and a plurality of pads 74. As illustrated in FIG. 1, the joint portion 71 is provided at one end of the FPC 37 and is attached to the actuator block 41. The joint portion 72 is provided at the other end of the FPC 37 and is attached to the bottom wall 25 of the base 21. The flexible portion 73 is provided between the joint portion 71 and the joint portion 72 and elastically bends in accordance with the rotation of the HSA 14.

As illustrated in FIG. 2, the plurality of pads 74 are provided in the joint portion 71. The pads 63 of a plurality of the flexures 53 are joined to the plurality of pads 74 by a solder 75. In other words, the pad 74 is connected to the flexure 53 by the solder 75. As a result, the flexure 53 electrically connects the FPC 37 and the magnetic head 54. The solder 75 is an example of a conductive adhesive. The conductive adhesive may be an adhesive including conductors such as silver fillers.

The VCM 15 in FIG. 1 rotates the carriage 35 about the central axis Axh. The carriage 35 rotates around the central axis Axh to move the magnetic head 54 to a desired position on the magnetic disk 12. The magnetic head 54 records and reproduces information on and from a recording layer of the magnetic disk 12. In other words, the magnetic head 54 reads and writes information from and to the magnetic disk 12.

When the magnetic head 54 moves to an outermost periphery of the magnetic disk 12 by the rotation of the carriage 35 by the VCM 15, the ramp load mechanism 16 holds the HGA 36. When the HGA 36 is held by the ramp load mechanism 16, the magnetic head 54 is separated from the magnetic disk 12.

The PCB 17 is, for example, a rigid board such as a glass epoxy board, and is a multilayer board, a build-up board, or the like. The PCB 17 is arranged outside the housing 11 and attached to the bottom wall 25 of the base 21.

Various electronic components are mounted on the PCB 17, such as a relay connector electrically connected to the FPC 37, an interface (I/F) connector connected to a host computer, and a controller that controls operation of the HDD 10. The relay connector is electrically connected to the joint portion 72 of the FPC 37 via a connector provided on the bottom wall 25.

The PCB 17 is electrically connected to the magnetic head 54 through the FPC 37 and the flexure 53. The controller of the PCB 17 controls the magnetic head 54 to read and write information from and to the magnetic disk 12.

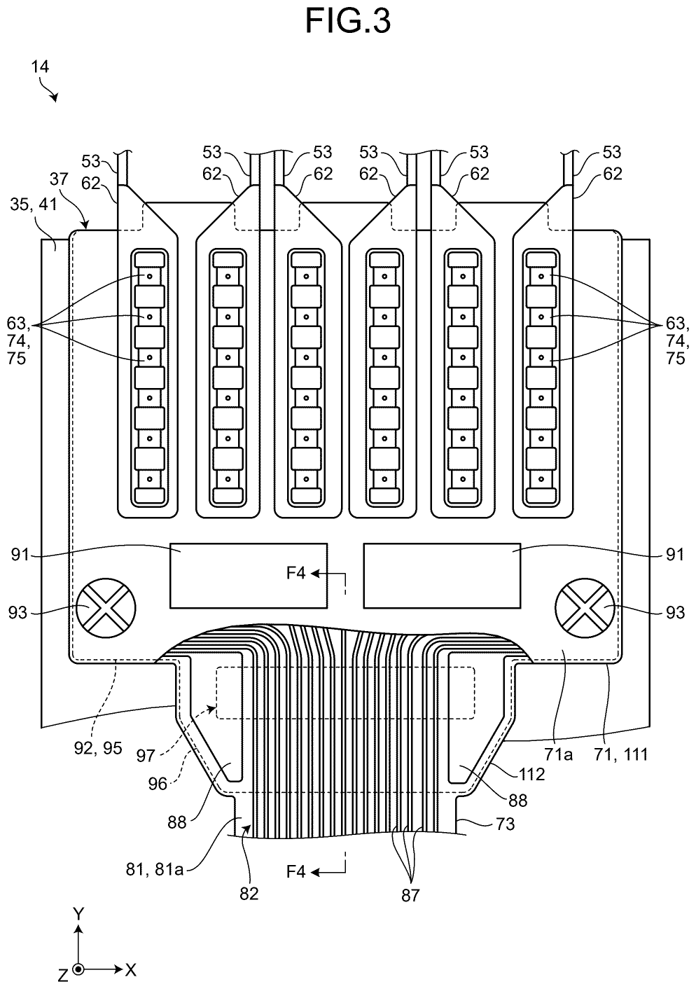

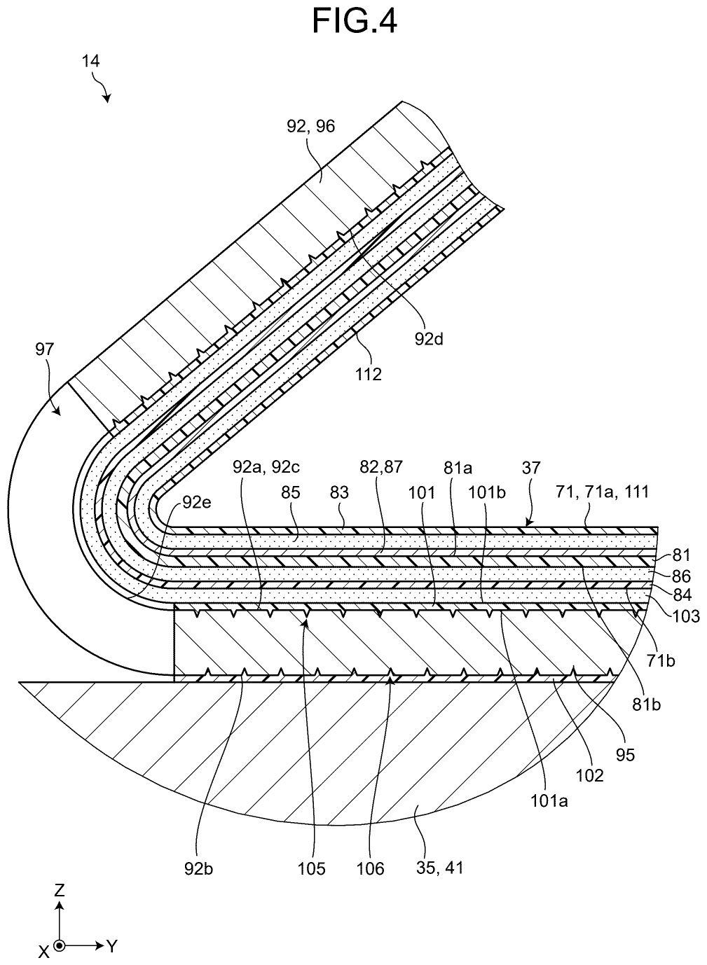

FIG. 3 is an exemplary plan view schematically illustrating the carriage 35, the FPC 37, and a part of the flexure 53 according to the first embodiment. FIG. 4 is an exemplary cross-sectional view schematically illustrating a part of the carriage 35 and the FPC 37 according to the first embodiment taken along line F4-F4 of FIG. 3. As illustrated in FIG. 4, the joint portion 71 of the FPC 37 has two surfaces 71a and 71b. The surface 71a is an example of a first surface. The surface 71b is an example of a second surface.

As illustrated in FIG. 3, the plurality of pads 74 are provided on the one surface 71a. Therefore, the surface 71a faces the tails 62 of the plurality of flexures 53. As illustrated in FIG. 4, the other surface 71b is located opposite to the surface 71a. The surface 71b faces the actuator block 41 of the carriage 35.

The FPC 37 has, for example, a base layer 81, a conductive layer 82, two cover layers 83 and 84, and two adhesive layers 85 and 86. Note that the FPC 37 is not limited to this example, and may have fewer layers or more layers. The joint portion 71, the joint portion 72, and the flexible portion 73 each have a part of each of the base layer 81, the conductive layer 82, the cover layers 83 and 84, and the adhesive layers 85 and 86.

The base layer 81 and the cover layers 83 and 84 are made of, for example, an insulating synthetic resin such as polyimide (PI). Note that the base layer 81 and the cover layers 83 and 84 are not limited to these examples, and may be made of different materials.

The base layer 81 has two surfaces 81a and 81b. The one surface 81a faces the tail 62 of the flexure 53. The other surface 81b is located opposite to the surface 81a and faces the actuator block 41 of the carriage 35.

The conductive layer 82 is provided on the surface 81a of the base layer 81. The conductive layer 82 is bonded to the surface 81a of the base layer 81 by, for example, an adhesive integrated with the base layer 81. Note that the conductive layer 82 is not limited to this example. In addition, the FPC 37 may further have another conductive layer provided on the other surface 81b.

The conductive layer 82 is made of, for example, a conductive material such as a copper foil. The conductive layer 82 has the plurality of pads 74. Furthermore, as illustrated in FIG. 3, the conductive layer 82 has a plurality of wirings 87 and a ground plane 88. Each of the plurality of wirings 87 transmits, for example, an electric signal, and supplies power, or is set to a ground potential. The ground plane 88 is provided along the surface 81a and is set to a ground potential.

As illustrated in FIG. 4, the cover layer 83 covers the surface 81a of the base layer 81 and the conductive layer 82. For example, the cover layer 83 and the pad 74 of the conductive layer 82 form the surface 71a of the joint portion 71. The cover layer 84 covers the surface 81b of the base layer 81. The cover layer 84 forms the surface 71b of the joint portion 71. Note that the surface 71a, 71b is not limited to this example.

The adhesive layer 85, 86 is made of, for example, an acrylic adhesive. The adhesive layer 85 fixes the cover layer 83 to the surface 81a of the base layer 81 and the conductive layer 82. The adhesive layer 86 fixes the cover layer 84 to the surface 81b of the base layer 81.

As illustrated in FIG. 3, the HSA 14 further has a plurality of preamplifiers 91, a reinforcing plate 92, and a plurality of screws 93. The preamplifier 91 is an example of an electronic component, a chip, and an amplifier. The preamplifier 91 may also be referred to as a head IC, a head amplifier, an IC, or a microchip. The reinforcing plate 92 is an example of a plate and a metal plate.

The preamplifier 91 is mounted on the surface 71a of the joint portion 71. The preamplifier 91 is electrically connected to the PCB 17 through at least one of the plurality of wirings 87. Furthermore, the preamplifier 91 is electrically connected to the plurality of pads 74 through at least one of the plurality of wirings 87.

The preamplifier 91 amplifies, for example, a write signal transmitted from the PCB 17 toward the magnetic head 54 to the FPC 37 and a read signal transmitted from the magnetic head 54 toward the PCB 17 to the FPC 37. The write signal corresponds to information to be written by the magnetic head 54 to the magnetic disk 12. The read signal corresponds to information read from the magnetic disk by the magnetic head 54.

The reinforcing plate 92 is made of metal such as stainless steel or aluminum alloy, for example, and is formed in a plate shape. Note that the reinforcing plate 92 is not limited to this example. The reinforcing plate 92 has higher rigidity than the FPC 37.

As illustrated in FIG. 4, the reinforcing plate 92 has two surfaces 92a and 92b. The surface 92a is an example of the third surface and a first outer surface. The surface 92b is an example of a fourth surface and a second outer surface.

The one surface 92a faces the surface 71b of the joint portion 71. The other surface 92b is located opposite to the surface 92a. At least a part of the surface 92b faces the actuator block 41 of the carriage 35.

The reinforcing plate 92 is partly bent. Thus, the reinforcing plate 92 has a flat portion 95 and a guide portion 96. Note that the reinforcing plate 92 is not limited to this example. Each of the flat portion 95 and the guide portion 96 has a part of each of the surfaces 92a and 92b.

The flat portion 95 is formed in a substantially flat plate shape. The flat portion 95 is arranged between the actuator block 41 of the carriage 35 and the joint portion 71 of the FPC 37. The flat portion 95 supports the tail 62 of the flexure 53 and the preamplifier 91 via the FPC 37.

The guide portion 96 extends from an edge of the flat portion 95 and is bent with respect to the flat portion 95. Note that the guide portion 96 illustrated in FIG. 3 is not bent for convenience sake, and extends straight from the flat portion 95.

As illustrated in FIG. 4, the surface 92a of reinforcing plate 92 has a plane 92c, an inclination 92d, and a curve 92e. The inclination 92d may be omitted from the surface 92a. The plane 92c is provided at the flat portion 95 and is formed to be substantially flat. The inclination 92d and the curve 92e are provided at the guide portion 96. The inclination 92d is inclined with respect to the plane 92c. The curve 92e is provided between the plane 92c and the inclination 92d, and is continuous with the plane 92c and the inclination 92d. The curve 92e is a curve bent in a substantially arc shape.

In the following, for convenience sake, an X axis, a Y axis, and a Z axis are defined. The X axis, the Y axis, and the Z axis are orthogonal to each other. The X axis is provided along a width of the plane 92c. The Y axis is provided along a length of the plane 92c. The Z axis is provided orthogonal to the plane 92c.

Furthermore, in the present specification, an X direction, a Y direction, and a Z direction are further defined. The X direction is a direction along the X axis and includes a +X direction indicated by an arrow of the X axis and a −X direction which is a direction opposite to the direction indicated by the arrow of the X axis. The Y direction is a direction along the Y axis and includes a +Y direction indicated by an arrow of the Y axis and a −Y direction which is a direction opposite to the direction indicated by the arrow of the Y axis. The Z direction is a direction along the Z axis and includes a +Z direction indicated by an arrow of the Z axis and a −Z direction which is a direction opposite to the direction indicated by the arrow of the Z axis.

As illustrated in FIG. 3, the plurality of pads 74 are arranged in the vicinity of an end of the joint portion 71 in the +Y direction. The plurality of pads 63 and 74 are arranged in the Y direction. The guide portion 96 of the reinforcing plate 92 extends from an end of the flat portion 95 in the −Y direction.

The guide portion 96 is provided with a through hole 97. The through hole 97 extends substantially in the X direction along the edge of the flat portion 95. The through hole 97 penetrates the guide portion 96 and facilitates bending of the guide portion 96. The through hole 97 may be omitted from the guide portion 96.

The screw 93 penetrates the joint portion 71 of the FPC 37 and the flat portion 95 of the reinforcing plate 92 and is bonded to the actuator block 41 of the carriage 35. Thus, the screw 93 attaches the joint portion 71 and the flat portion 95 to the actuator block 41. The two screws 93 are arranged at both ends of the joint portion 71 and the flat portion 95 in the X direction.

As illustrated in FIG. 4, the HSA 14 further has two bonding layers 101 and 102 and an adhesive 103. The bonding layer 101 is an example of the first bonding layer. The bonding layer 102 is an example of a second bonding layer. The adhesive 103 is an example of the first adhesive.

The bonding layer 101, 102 is an organic compound, and is, for example, a primer. The bonding layer 101, 102 may be a film made of other organic material. The bonding layer 101 is provided on the one surface 92a of the reinforcing plate 92 and directly adheres to the surface 92a. The bonding layer 102 is provided on the other surface 92b of the reinforcing plate 92 and directly adheres to the surface 92b.

The adhesive 103 is, for example, an acrylic adhesive. The adhesive 103 is not limited to this example, and may be made of other organic material such as polyolefin. The adhesive 103 is provided on the surface 71b of the joint portion 71.

The adhesive 103 fixes the bonding layer 101 to the surface 71b of the joint portion 71. In other words, the adhesive 103 fixes the surface 92a of the reinforcing plate 92 provided with the bonding layer 101 to the surface 71b of the joint portion 71.

The bonding layer 101, 102 allows the adhesive 103 to adhere more easily than the surface 92a of the reinforcing plate 92 made of stainless steel or aluminum alloy does. For example, the reinforcing plate 92 provided with the bonding layer 101 firmly adheres to the adhesive 103 by a non-covalent bond such as a hydrogen bond.

The bonding layer 101 has two surfaces 101a and 101b. The surface 101a is an example of a fifth surface. The surface 101b is an example of a sixth surface. The one surface 101a directly adheres to the surface 92a of the reinforcing plate 92. The other surface 101b is located opposite to the surface 101a and adheres directly to the adhesive 103.

The bonding layer 101 enters a fine recess 105 existing in the surface 92a of the reinforcing plate 92. On the other hand, the surface 101b of the bonding layer 101 is lower in surface roughness than the surface 92a of the reinforcing plate 92. For this reason, the bonding layer 101 adheres to the adhesive 103 with almost no gap, and bonding between the reinforcing plate 92 and the adhesive 103 is strengthened by an anchor effect. The bonding layer 102 also enters a fine recess 106 existing in the surface 92b of the reinforcing plate 92. The recesses 105 and 106 are formed by fine irregularities that cause surface roughness in the surfaces 92a and 92b, and are exaggerated in the drawings.

A gap is hardly generated between the bonding layer 101 and the surface 92a of the reinforcing plate 92. In addition, a gap is hardly generated between the bonding layer 101 and the adhesive 103. Therefore, moisture is less likely to exist between the bonding layer 101 and the reinforcing plate 92 and between the bonding layer 101 and the adhesive 103.

In the present embodiment, the FPC 37, the bonding layer 101, and the adhesive 103 cover an entire area of the one surface 92a of the reinforcing plate 92. In other words, the bonding layer 101 is provided over the entire surface 92a of the reinforcing plate 92. The adhesive 103 adheres to the entire area of the surface 101b of the bonding layer 101. The adhesive 103 fixes the entire area of the surface 101b of the bonding layer 101 and the FPC 37 to each other. In the present embodiment, the FPC 37 also covers the through hole 97.

The joint portion 71 has a flat portion 111 and a bent portion 112. The flat portion 111 is fixed to the flat portion 95 of the reinforcing plate 92 by the adhesive 103. The bent portion 112 extends from an end of the flat portion 111 in the −Y direction and is bonded to the guide portion 96 of the reinforcing plate 92. In other words, the bent portion 112 is fixed to the curve 92e via the adhesive 103 and the bonding layer 102. The bent portion 112 is connected to the flexible portion 73.

When the carriage 35 rotates about the central axis Axh, the reinforcing plate 92 also rotates about the central axis Axh. The flexible portion 73 of the FPC 37 is elastically deformed following the rotation of the reinforcing plate 92. Since the bent portion 112 of the FPC 37 is bonded to the entire inclination 92d and the entire curve 92e of the guide portion 96, a bonding area between the FPC 37 and the guide portion 96 increases. As a result, the followability of the flexible portion 73 with respect to the rotation of the carriage 35 is improved.

As illustrated in FIG. 3, a part of the wiring 87 and a part of the ground plane 88 are provided in the bent portion 112. A part of the wiring 87 extends so as to cross the through hole 97 of the guide portion 96. A part of the ground plane 88 is provided between both ends of the bent portion 112 in the X direction and the plurality of wirings 87. Note that the wiring 87 and the ground plane 88 are not limited to this example.

As shown in FIG. 4, the bonding layer 102 contacts the actuator block 41 of the carriage 35 and is arranged between the reinforcing plate 92 and the actuator block 41. The reinforcing plate 92 is supported by the actuator block 41 via the bonding layer 102. Substantially the entire bonding layer 102 is covered by the actuator block 41. Note that the bonding layer 102 may be covered with other member or may be separated from the actuator block 41.

At the time of assembling the HDD 10 described above, pads 65 of the flexures 53 are joined to the pads 74 of the FPC 37 by the solder 75. For example, a paste containing the solder 75 is applied to one of the pad 65 and the pad 74. Next, the tail 62 of the flexure 53 and the joint portion 71 of the FPC 37 are overlapped, and the paste is attached to the other of the pad 65 and the pad 74.

Next, for example, the tail 62 and the joint portion 71 are irradiated with laser light. The laser light is an area laser, and is radiated to a relatively wide range of the tail 62 and the joint portion 71. Note that the laser light is not limited to this example.

The laser light is radiated to the tail 62 and the joint portion 71, and is radiated to the solder 75 through, for example, a hole provided in the tail 62. Heat is transferred to the solder 75 from the tail 62 and the joint portion 71 heated by the laser light. Furthermore, the solder 75 is directly heated by the laser light. As a result, the paste is melted, and the pad 65 and the pad 74 are joined by the solder 75. On the other hand, the joint portion 71 heated by the laser light dissipates heat to the reinforcing plate 92.

When a bonding force of the adhesive 103 between the joint portion 71 and the reinforcing plate 92 is weak, delamination might occur between the reinforcing plate 92 and the adhesive 103 due to, for example, moisture. A gap between the reinforcing plate 92 and the adhesive 103 prevents heat conduction from the joint portion 71 to the reinforcing plate 92. In this case, the joint portion 71 is excessively heated, so that delamination might occur between the conductive layer 82 and the base layer 81, or the joint portion 71 might be burnt.

In the HDD 10 according to the present embodiment, since the bonding layer 101 strengthens the bonding force of the adhesive 103, it is possible to suppress peeling of the reinforcing plate 92 from the adhesive 103. Therefore, the joint portion 71 can dissipate heat through the reinforcing plate 92, and eventually, it is possible to suppress occurrence of delamination between the conductive layer 82 and the base layer 81 and burning of the joint portion 71.

While the bonding layers 101 and 102 strengthen the bonding force of the adhesive 103, contaminants such as dust are likely to adhere. In addition, contaminants adhering to the bonding layer 101, 102 are hardly removed by cleaning. In the HDD 10 according to the present embodiment, by covering the entire area of the surface 101a of the bonding layer 101 with the FPC 37 and the adhesive 103, it is possible to suppress adhesion of contaminants to the bonding layer 101. In addition, the bonding layer 102 is covered by the actuator block 41 of the carriage 35 and thus protected from contaminants by the actuator block 41.

In the HDD 10 according to the first embodiment described above, the FPC 37 has the surface 71a, the surface 71b, and the pad 74. The surface 71a faces the flexure 53. The surface 71b is located opposite to the surface 71a. The pad 74 is provided on the surface 71a and is connected to the flexure 53 by the solder 75. The adhesive 103 is provided on the surface 71b. The reinforcing plate 92 has the surface 92a facing the surface 71b.

The bonding layer 101 is provided on the surface 92a, enters the recess 105 of the surface 92a, and is fixed to the surface 71b by the adhesive 103. Thus, the bonding layer 101 can strengthen the bonding between the reinforcing plate 92 and the adhesive 103 by, for example, an anchor effect.

The solder 75 is heated at the time of joining. The bonding layer 101 increases the bonding force of the adhesive 103. For this reason, the bonding layer 101 can suppress peeling of the reinforcing plate 92 from the adhesive 103, for example, at the time of heating the solder 75. Since the reinforcing plate 92 is continuously fixed to the FPC 37 by the adhesive 103, it is possible to dissipate heat of the FPC 37, and eventually, it is possible to suppress the FPC 37 from being damaged by heat.

The housing 11 houses the flexure 53, the FPC 37, the adhesive 103, the reinforcing plate 92, and the bonding layer 101. The magnetic disk 12 is housed in the housing 11. The magnetic head 54 is configured to read and write information from and to the magnetic disk 12. The carriage 35 is configured to rotate to move the magnetic head 54. The flexure 53 is connected to the pad 74 by the solder 75, and electrically connects the FPC 37 and the magnetic head 54. The reinforcing plate 92 is attached to the carriage 35.

The solder 75 connecting the pad 74 of the FPC 37 and the flexure 53 is heated by being irradiated with laser light, for example. The bonding layer 101 increases the bonding force of the adhesive 103. For this reason, the bonding layer 101 can suppress peeling of the reinforcing plate 92 from the adhesive 103, for example, at the time of heating the solder 75.

The reinforcing plate 92 has the surface 92b located opposite to the surface 92a and facing the carriage 35. The bonding layer 102 is provided on the surface 92b and enters the recess 106 of the surface 92b.

The bonding layers 101 and 102 are provided on the surfaces 92a and 92b of the reinforcing plate 92, respectively. Therefore, the reinforcing plate 92 can be easily applied the material of the bonding layer 101, 102 by, for example, immersion, as compared with a case where the bonding layer 102 is not provided on the surface 92b. Therefore, the HDD 10 can be easily manufactured.

The bonding layer 101 is provided over the entire area of the surface 92a. Therefore, as compared with a case where the bonding layer 101 is provided only on a part of the surface 92a, it is, for example, not necessary to provide a mask on the surface 92a, and the surface 92a can be easily applied the material. Therefore, the HDD 10 can be easily manufactured.

The bonding layer 101 has the surface 101a attached to the surface 92a and the surface 101b located opposite to the surface 101a. The adhesive 103 adheres to the entire area of the surface 101b. In other words, the adhesive 103 covers the entire bonding layer 101. For this reason, the adhesive 103 can suppress adhesion of contaminants to the bonding layer 101, and can eventually suppress contamination of the inside of the housing 11.

The adhesive 103 fixes the entire area of the surface 101b and the FPC 37 to each other. In other words, the FPC 37 covers the entire bonding layer 101. For this reason, the FPC 37 can suppress adhesion of contaminants to the bonding layer 101, and can eventually suppress contamination of the inside of the housing 11.

The surface 92a has the plane 92c and the curve 92e continuous from the plane 92c. The FPC 37 has the ground plane 88. A part of the ground plane 88 is provided in the bent portion 112, of the FPC 37, fixed to the curve 92e via the adhesive 103 and the bonding layer 101.

The curve 92e bends the FPC 37 and generates an elastic force in the FPC 37. Therefore, in a general HDD, the curve is hardly bonded to the FPC and is partly exposed. However, in the present embodiment, since the bonding layer 101 increases the bonding force of the adhesive 103, the FPC 37 can be fixed to the curve 92e via the adhesive 103 and the bonding layer 101. In the HDD 10 according to the present embodiment, the FPC 37 extends over the entire curve 92e and can expand the ground plane 88. Therefore, the FPC 37 can improve electrical characteristics.

The magnetic disk 12 is housed in the housing 11. The magnetic head 54 is configured to read and write information from and to the magnetic disk 12. The carriage 35 is configured to rotate to move the magnetic head 54. The FPC 37 has the pad 74. The flexure 53 is joined to the pad 74 by solder 75, and electrically connects the FPC 37 and the magnetic head 54. The reinforcing plate 92 has the surfaces 92a and 92b. The surface 92a faces the FPC 37 and has an entire area covered with the FPC 37. The surface 92b is located opposite to the surface 92a and faces the carriage 35. The reinforcing plate 92 is attached to the carriage 35.

The metal surfaces 92a and 92b of the reinforcing plate 92 are generally rougher than the surfaces 71a and 71b of the FPC 37, and contaminants easily adhere thereto. However, the entire area of the surface 92a of the reinforcing plate 92 is covered with the FPC 37. As a result, the HDD 10 can suppress adhesion of contaminants to the surface 92a, and can eventually suppress contamination of the inside of the housing 11.

The bonding layer 101 has an organic compound and is directly attached to the surface 92a. Thus, the bonding layer 101 can strengthen the bonding between the reinforcing plate 92 and the adhesive 103 by, for example, non-covalent bond.

### Second Embodiment

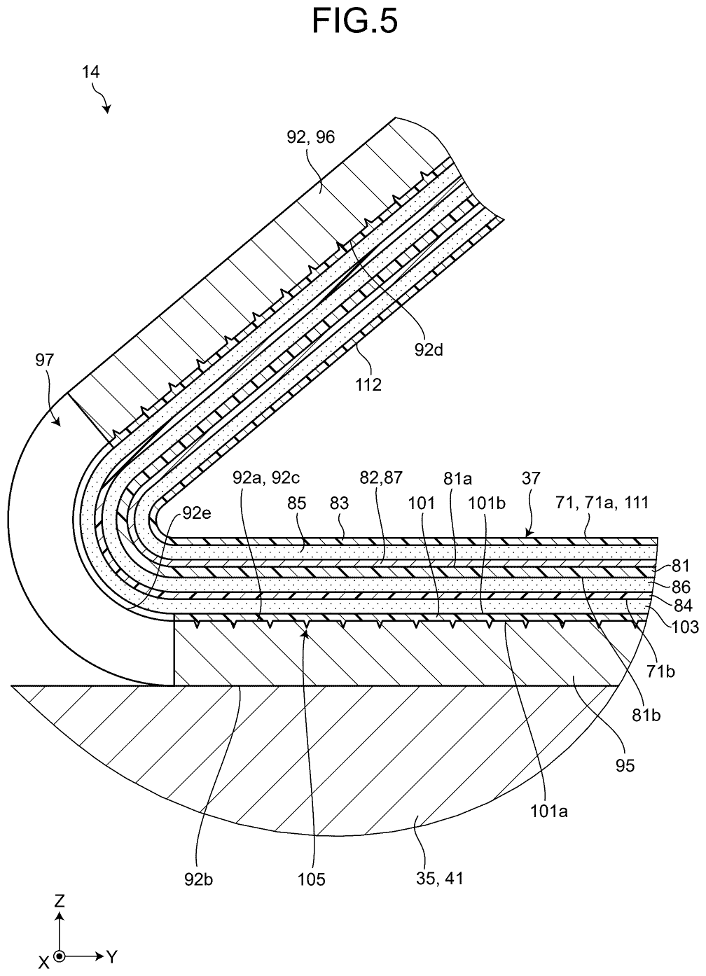

In the following, a second embodiment will be described with reference to FIG. 5. In the following description of a plurality of embodiments, components having functions similar to those of the components already described are denoted by the same reference numerals as those of the components already described, and description thereof may be omitted. In addition, the plurality of components denoted by the same reference numerals do not necessarily have all the functions and properties in common, and may have different functions and properties according to each embodiment.

FIG. 5 is an exemplary cross-sectional view schematically illustrating a part of the carriage 35 and the FPC 37 according to the second embodiment. As shown in FIG. 5, in the second embodiment, the HSA 14 does not have the bonding layer 102. Thus, the surface 92b of the reinforcing plate 92 contacts the actuator block 41 of the carriage 35.

For example, the reinforcing plate 92 is made of one metal plate. For example, the metal plate is applied the material of the bonding layer 101 by being immersed in the material of the bonding layer 101. Before immersion, a mask is provided on one surface of the metal plate to be the surface 92b. As a result, although the bonding layer 101 is formed on the surface 92a, the bonding layer 102 is not formed on the surface 92b.

The reinforcing plate 92 is cut out from the metal plate. For this reason, the bonding layer is not provided on an edge of the reinforcing plate 92 either. The cut reinforcing plate 92 is bent to provide the flat portion 95 and the guide portion 96 in the reinforcing plate 92.

In the HDD 10 of the second embodiment described above, the reinforcing plate 92 has the surface 92b that is located opposite to the surface 92a and is in contact with the carriage 35. In other words, the surface 92b is in direct contact with the carriage 35 and is not covered by the bonding layer 102. Therefore, the HDD 10 can suppress adhesion of contaminants to the bonding layer 102, and can eventually suppress contamination of the inside of the housing 11.

### Third Embodiment

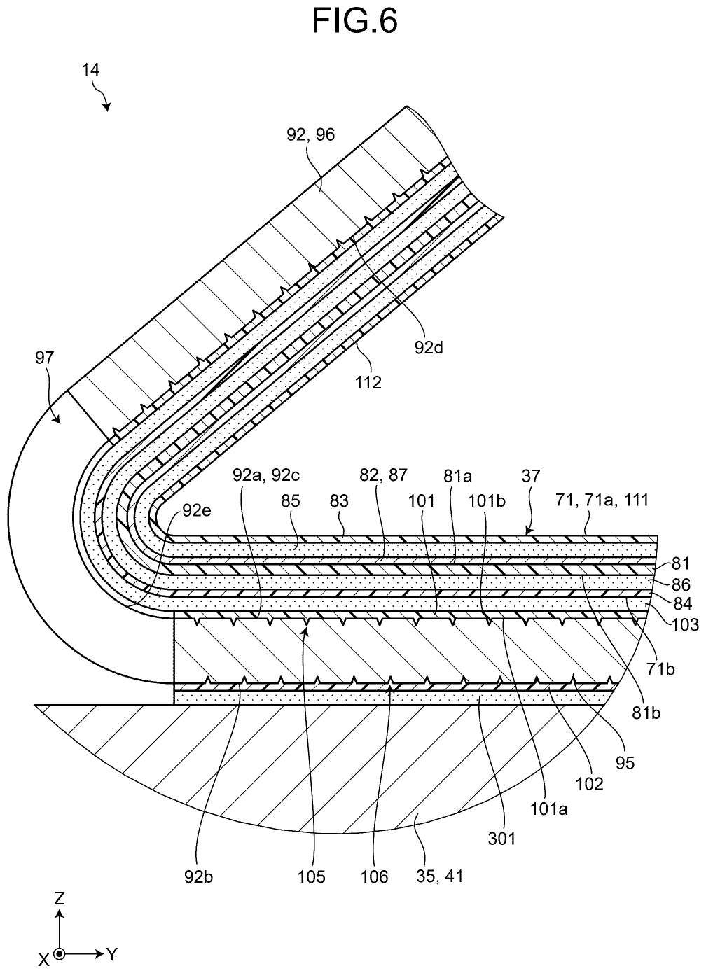

In the following, a third embodiment will be described with reference to FIG. 6. FIG. 6 is an exemplary cross-sectional view schematically illustrating a part of the carriage 35 and the FPC 37 according to the third embodiment. As illustrated in FIG. 6, the HSA 14 of the third embodiment further has an adhesive 301. The adhesive 301 is an example of a second adhesive.

Like the adhesive 103, the adhesive 301 is an acrylic adhesive. The adhesive 301 may be different from the adhesive 103. The adhesive 301 fixes the bonding layer 102 and the actuator block 41 of the carriage 35 to each other.

In the present embodiment, the adhesive 301 is interposed between the entire bonding layer 102 and the carriage 35. Therefore, the adhesive 301 covers the entire bonding layer 102. The adhesive 301 may cover a part of the bonding layer 102.

In the HDD 10 of the third embodiment described above, the adhesive 301 fixes the bonding layer 102 and the carriage 35 to each other. In general, not only the adhesive 103, 301 but also other substances such as contaminants are easily attached to the bonding layer 102. However, the bonding layer 102 is covered with the adhesive 301. As a result, the HDD 10 can suppress adhesion of contaminants to the bonding layer 102, and can eventually suppress contamination of the inside of the housing 11. Furthermore, the adhesive 301 firmly fixes the reinforcing plate 92 to the carriage 35, and can eventually suppress displacement and vibration of the reinforcing plate 92 with respect to the carriage 35.

### Fourth Embodiment

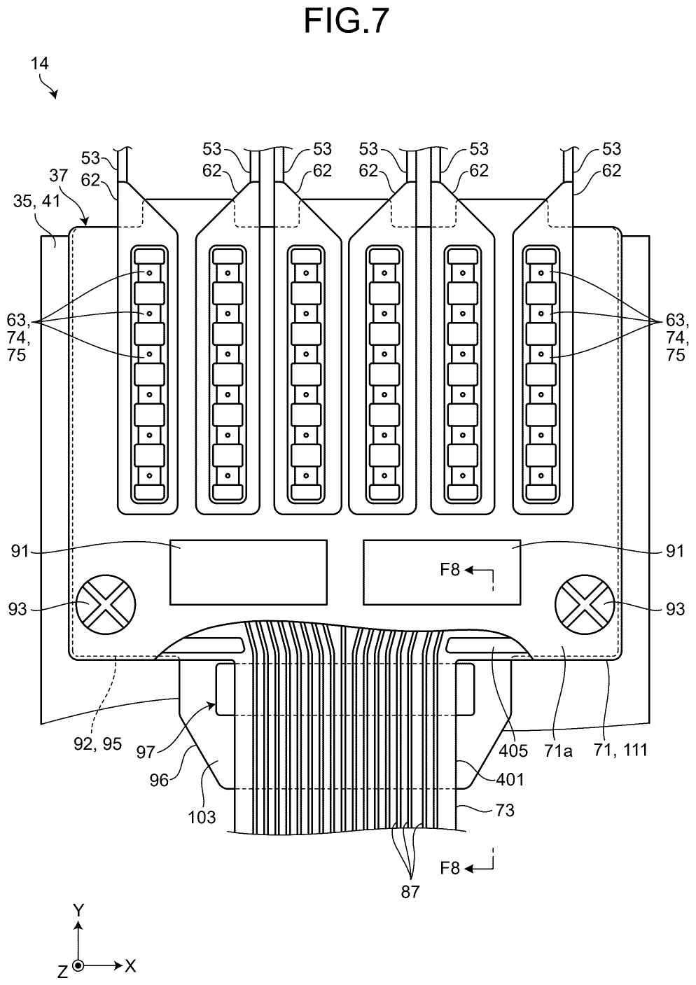

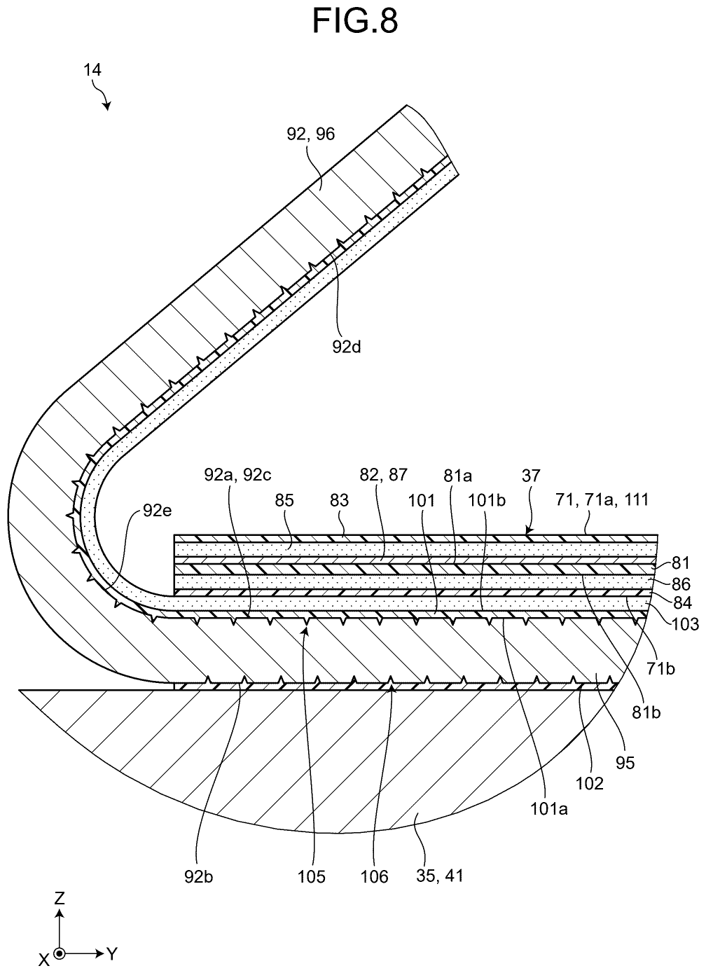

In the following, a fourth embodiment will be described with reference to FIGS. 7 and 8. FIG. 7 is an exemplary plan view schematically illustrating the carriage 35, the FPC 37, and a part of the flexure 53 according to the fourth embodiment. FIG. 8 is an exemplary cross-sectional view schematically illustrating a part of the carriage 35 and the FPC 37 of the fourth embodiment taken along line F8-F8 of FIG. 7.

As shown in FIG. 7, the joint portion 71 of the fourth embodiment has a bent portion 401 instead of the bent portion 112. The bent portion 401 is substantially equal to the bent portion 112 except points as will be described below. The bent portion 401 partly covers the surface 92a of the guide portion 96 of the reinforcing plate 92. The bent portion 401 is provided with the plurality of wirings 87.

The FPC 37 of the fourth embodiment has a ground plane 405 instead of the ground plane 88. The ground plane 405 is substantially equal to the ground plane 88 except points as described below. The ground plane 405 is not provided in the bent portion 401 but is provided in the flat portion 111. Therefore, the ground plane 405 is separated from the bent portion 401.

The adhesive 103 covers the entire area of the surface 92a and adheres to the entire area of the surface 101b of the bonding layer 101. In other words, a part of the bonding layer 101 provided on the surface 92a is covered with the adhesive 103 and the bent portion 401, and the remaining part of the bonding layer 101 is covered with the adhesive 103. The solidified adhesive 103 covers the surface 101b of the bonding layer 101 as a synthetic resin layer.

In the HDD 10 of the fourth embodiment described above, the surface 92a has the plane 92c and the curve 92e continuous from the plane 92c. The FPC 37 has the ground plane 405. The ground plane 405 is separated from the bent portion 401 fixed to the curve 92e of the FPC 37 via the adhesive 103 and the bonding layer 101.

The bent portion 401 of the FPC 37 is bent along the curve 92e. On the other hand, the ground plane 405 improves the rigidity of the FPC 37. Since the ground plane 405 is separated from the bent portion 401, the FPC 37 can be easily bent along the curve 92e.

### Fifth Embodiment

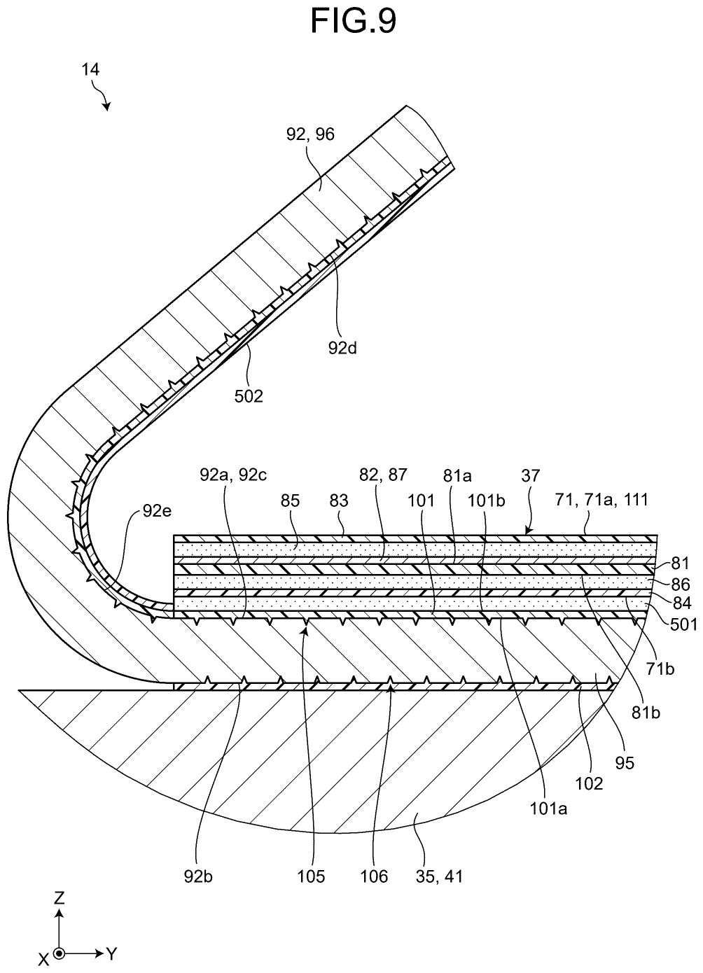

In the following, a fifth embodiment will be described with reference to FIG. 9. FIG. 9 is an exemplary cross-sectional view schematically illustrating the carriage 35 and the FPC 37 according to the fifth embodiment. The joint portion 71 of the fifth embodiment has the bent portion 401 instead of the bent portion 112 as in the fourth embodiment. Also as illustrated in FIG. 9, the HSA 14 of the fifth embodiment includes an adhesive 501 and an outer layer 502 instead of the adhesive 103. The adhesive 501 is substantially equal to the adhesive 103 except points as will be described below.

The adhesive 501 adheres to the entire area of the surface 101b of the bonding layer 101 provided on the plane 92c and to the surface 101b on a part of the bonding layer 101 provided on the inclination 92d and the curve 92e. The bent portion 401 is fixed to the reinforcing plate 92 via the adhesive 501 and the bonding layer 101. The adhesive 501 may not adhere to the bonding layer 101 provided on the inclination 92d and the curve 92e.

The outer layer 502 adheres to the surface 101b on the remaining part of the bonding layer 101, the remaining part being provided on the inclination 92d and the curve 92e. Therefore, the entire area of the surface 101b of the bonding layer 101 adheres to the adhesive 501 and the outer layer 502. The FPC 37 makes the outer layer 502 be exposed without being covered. Note that the FPC 37 may cover a part of the outer layer 502.

The outer layer 502 is made of an organic material such as polyolefin, for example. Note that the outer layer 502 is not limited to this example. The outer layer 502 is a substance different from the adhesive 501. The adhesive 501 is less likely to adhere to the outer layer 502 than to the bonding layer 101. Therefore, contaminants are also less likely to adhere to the outer layer 502.

In the HDD 10 of the fifth embodiment described above, the outer layer 502 is different from the adhesive 501. The bonding layer 101 has the surfaces 101a and 101b. The surface 101a adheres to the surface 92a. The surface 101b is located opposite to the surface 101a, and the entire area thereof adheres to the adhesive 501 and the outer layer 502. In other words, the adhesive 501 and the outer layer 502 cover the entire bonding layer 101. For this reason, the adhesive 501 and the outer layer 502 can suppress adhesion of contaminants to the bonding layer 101, and can eventually suppress contamination of the inside of the housing 11.

### Sixth Embodiment

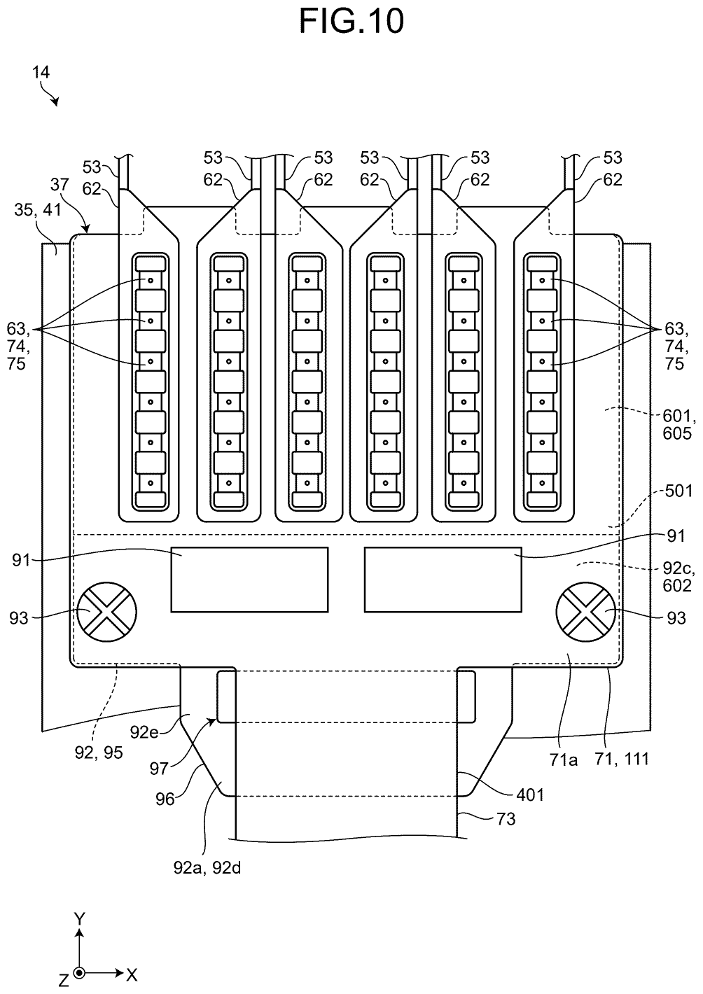

In the following, a sixth embodiment will be described with reference to FIG. 10. FIG. 10 is an exemplary plan view schematically illustrating the carriage 35, the FPC 37, and a part of the flexure 53 according to the sixth embodiment. As shown in FIG. 10, the joint portion 71 of the sixth embodiment has the bent portion 401 instead of the bent portion 112 as in the fourth embodiment. In addition, the HSA 14 of the sixth embodiment includes the adhesive 501 instead of the adhesive 103 as in the fifth embodiment.

The surface 92a of the reinforcing plate 92 of the sixth embodiment has two regions 601 and 602. The region 601 is an example of a first region. The region 602 is an example of a second region. Each of the regions 601 and 602 is a part of the surface 92a. In FIG. 10, for convenience sake, the region 601 and the region 602 are separated by a broken line.

The region 601 has a part of the plane 92c. The region 601 overlaps the plurality of pads 74 of the FPC 37, the tails 62 of the plurality of flexures 53, and the plurality of solders 75 in the Z direction. The Z direction is a direction orthogonal to the plane 92c of the surface 92a. Therefore, the region 601 supports the plurality of tails 62 via the FPC 37.

The region 602 has the remaining part of the plane 92c, the inclination 92d, and the curve 92e. The region 602 is adjacent to the region 601. The region 602 is separated from the plurality of pads 74 of the FPC 37, the tails 62 of the plurality of flexures 53, and the plurality of solders 75 in the −Y direction. The −Y direction is a direction along the plane 92c of the surface 92a. The region 602 supports the preamplifier 91. Furthermore, a hole through which the screw 93 passes opens in the region 602.

In the sixth embodiment, the HSA 14 has a bonding layer 605 instead of the bonding layer 101. The bonding layer 605 is substantially equal to the bonding layer 101 except points as will be described below. The bonding layer 605 is provided in the region 601 and is separated from the region 602. In other words, the bonding layer 605 is not provided in the region 602.

A part of the adhesive 501 fixes the bonding layer 605 provided in the region 601 to the surface 71b of the joint portion 71. The adhesive 501 adheres to the entire area of the surface 101b of the bonding layer 605. The remaining part of the adhesive 501 fixes the region 602 to the surface 71b.

In the region 602, a part of the inclination 92d and a part of the curve 92e are exposed without being covered with the bent portion 401, the adhesive 501, and the bonding layer 605. Note that the inclination 92d and the curve 92e are not limited to this example.

In the HDD10 of the sixth embodiment described above, the surface 92a has the regions 601 and 602. The region 601 overlaps the solder 75 in the Z direction orthogonal to the surface 92a. The region 602 is separated from the solder 75 in the −Y direction along the surface 92a. The bonding layer 605 is provided in the region 601 and is separated from the region 602. As a result, the bonding layer 605 can improve a bonding force of the adhesive 501 in the vicinity of the solder 75 to be heated, and can eventually suppress peeling of the reinforcing plate 92 from the adhesive 501 at the time of heating the solder 75. Furthermore, the HDD 10 enables reduction in cost as compared with a case where the bonding layer 605 is provided over the entire surface 92a.

### Seventh Embodiment

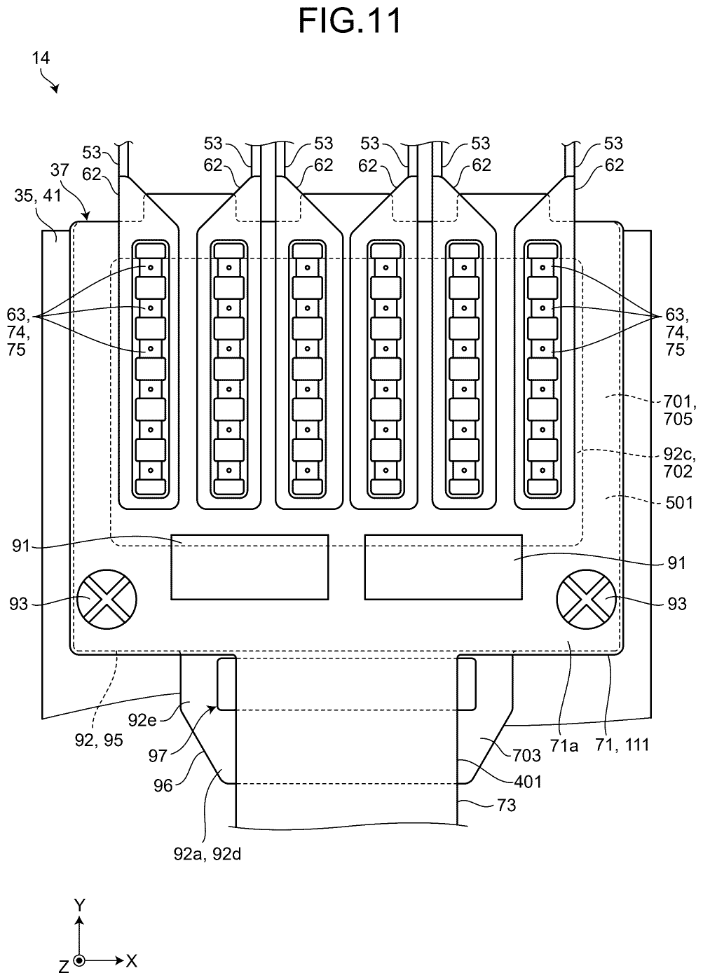

In the following, a seventh embodiment will be described with reference to FIG. 11. FIG. 11 is an exemplary plan view schematically illustrating the carriage 35, the FPC 37, and a part of the flexure 53 according to the seventh embodiment. The joint portion 71 of the seventh embodiment has the bent portion 401 instead of the bent portion 112 as in the fourth embodiment. In addition, the HSA 14 of the seventh embodiment has the adhesive 501 instead of the adhesive 103 as in the fifth embodiment.

The surface 92a of the reinforcing plate 92 of the seventh embodiment has three regions 701, 702, and 703. The region 701 is an example of a third region. The region 702 is an example of a fourth region. Each of the regions 701, 702, and 703 is a part of the surface 92a. In FIG. 11, for convenience sake, the region 701, the region 702, and the region 703 are separated by a broken line.

The region 701 has a part of the plane 92c. The region 702 has the remaining part of the plane 92c. The region 703 has the inclination 92d and the curve 92e. The region 701 surrounds the region 702. Each of the regions 701 and 702 overlaps the plurality of pads 74 of the FPC 37, the tails 62 of the plurality of flexures 53, and the plurality of solders 75 in the Z direction. One of the regions 701 and 702 may not overlap the solder 75.

In the seventh embodiment, the HSA 14 has a bonding layer 705 instead of the bonding layer 101. The bonding layer 705 is substantially equal to the bonding layer 101 except points as will be described below. The bonding layer 705 is provided in the region 701 and is separated from the regions 702 and 703. In other words, the bonding layer 705 is not provided in the regions 702 and 703. The region 702 is surrounded by the bonding layer 705 provided in the region 701.

A part of the adhesive 501 fixes the bonding layer 705 provided in the region 701 to the surface 71b of the joint portion 71. The adhesive 501 adheres to the entire area of the surface 101b of the bonding layer 705. The remaining part of the adhesive 501 fixes the region 702 to the surface 71b. The region 703 is exposed without being covered with the bent portion 401, the adhesive 501, and the bonding layer 705. Note that the region 703 is not limited to this example.

In 10 of the seventh embodiment described above, the surface 92a has the region 701 and the region 702. In the region 701, the bonding layer 705 is provided. The region 702 is surrounded by the bonding layer 705 provided in the region 701 and fixed to the surface 92b by the adhesive 501. As a result, the bonding layer 705 can suppress entry of external moisture into the adhesive 501 that fixes the region 702 and the surface 92b to each other, and can eventually suppress the moisture from causing peeling between the adhesive 501 and the region 702.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A disk device comprising:
an electronic component;
a flexible printed circuit board having a first surface facing the electronic component, a second surface located opposite to the first surface, and a pad provided on the first surface and connected to the electronic component by a conductive adhesive;
a first adhesive provided on the second surface;
a plate having a third surface facing the second surface; and
a first bonding layer provided on the third surface, entering a recess of the third surface, and fixed to the second surface by the first adhesive.

2. The disk device according to claim 1, further comprising:
a housing that houses the electronic component, the flexible printed circuit board, the first adhesive, the plate, and the first bonding layer;
a magnetic disk housed in the housing;
a magnetic head configured to read and write information from and to the magnetic disk; and
a carriage configured to rotate to move the magnetic head, wherein
the electronic component has a flexure that is connected to the pad by the joint body and electrically connects the flexible printed circuit board and the magnetic head, and
the plate is attached to the carriage.

3. The disk device according to claim 2, further comprising
a second bonding layer, wherein
the plate has a fourth surface that is located opposite to the third surface and faces the carriage, and
the second bonding layer is provided on the fourth surface and enters a recess of the fourth surface.

4. The disk device according to claim 3, further comprising
a second adhesive that fixes the second bonding layer and the carriage to each other.

5. The disk device according to claim 2, wherein
the plate has a fourth surface located opposite to the third surface and in contact with the carriage.

6. The disk device according to claim 1, wherein
the first bonding layer is provided over an entire area of the third surface.

7. The disk device according to claim 6, wherein
the first bonding layer has a fifth surface adhering to the third surface and a sixth surface located opposite to the fifth surface, and
the first adhesive adheres to an entire area of the sixth surface.

8. The disk device according to claim 7, wherein
the first adhesive fixes the entire area of the sixth surface and the flexible printed circuit board to each other.

9. The disk device according to claim 8, wherein
the third surface has a plane and a curve continuous from the plane,
the flexible printed circuit board has a ground plane, and
a part of the ground plane is provided in a part of the flexible printed circuit board fixed to the curve via the first adhesive and the first bonding layer.

10. The disk device according to claim 8, wherein
the third surface has a plane and a curve continuous from the plane,
the flexible printed circuit board has a ground plane, and
the ground plane is separated from a part of the flexible printed circuit board fixed to the curve via the first adhesive and the first bonding layer.

11. The disk device according to claim 6, further comprising
an outer layer different from the first adhesive, wherein
the first bonding layer has a fifth surface adhering to the third surface, and a sixth surface located opposite to the fifth surface and having an entire area adhering to the first adhesive and the outer layer.

12. The disk device according to claim 1, wherein
the third surface has a first region overlapping the joint body in a direction orthogonal to the third surface, and a second region separated from the joint body in a direction along the third surface, and
the first bonding layer is provided on the first region and is separated from the second region.

13. The disk device according to claim 1, wherein
the third surface has a third region on which the first bonding layer is provided, and a fourth region that is surrounded by the first bonding layer provided on the third region and that is fixed to the second surface by the first adhesive.

14. The disk device according to claim 1, wherein
the first bonding layer has an organic compound and directly adheres to the third surface.

15. The disk device according to claim 1, wherein
the electronic component is a chip.

16. The disk device according to claim 1, wherein
the electronic component is an amplifier.

17. A disk device comprising:
a housing;
a magnetic disk housed in the housing;
a magnetic head configured to read and write information from and to the magnetic disk;
a carriage configured to rotate to move the magnetic head;
a flexible printed circuit board having a pad;
a flexure that is connected to the pad by a conductive adhesive and electrically connects the flexible printed circuit board and the magnetic head; and
a metal plate having a first outer surface facing the flexible printed circuit board and having an entire area covered by the flexible printed circuit board, and a second outer surface located opposite to the first outer surface and facing the carriage, the metal plate being attached to the carriage.
